(19) United States
(12) Patent Application Publication
(10) Pub. No.: US 2020/0211729 A1
(43) Pub. Date: Jul. 2, 2020

(54) CONDUCTIVE PASTES FOR PATTERN TRANSFER PRINTING

(71) Applicant: Heraeus Precious Metals North America Conshohocken LLC, West Conshohocken, PA (US)

(72) Inventors: Vinodh Chandrasekaran, West Conshohocken, PA (US); Matthias Hoerteis, Bryn Mawr, PA (US)

(21) Appl. No.: 16/234,965

(22) Filed: Dec. 28, 2018

(51) Int. Cl. H01B 1/22; H01L 31/0224; H01L 31/18

(52) U.S. Cl. CPC H01B 1/22; H01L 31/1892; H01L 31/022425

(57) ABSTRACT

A conductive paste for use in a laser-induced pattern transfer printing process includes a conductive component; a glass component; and an inorganic vehicle, wherein the conductive paste exhibits a light reflectance of no more than 50% across a light wavelength range of about 800 to about 1300 nm and improving the transfer of the paste to the substrate. A process for laser-induced pattern transfer printing includes providing a first substrate comprising a recessed surface and a conductive paste disposed in the recessed surface; orienting the recessed surface of the first substrate toward a second substrate; irradiating the conductive paste with a laser, the laser configured to emit light having a wavelength between about 800 and about 1300 nm; and transferring the irradiate conductive paste from the first substrate to a surface of the second substrate.

### FIELD OF THE INVENTION

The invention relates to conductive pastes for use in pattern transfer printing processes. More specifically, the invention relates to the fabrication of finger lines and bus bars, from conductive pastes, on photovoltaic device substrates in laser pattern transfer printing processes.

### BACKGROUND OF THE DISCLOSURE

Solar cells are generally made of semiconductor materials, such as silicon (Si), which convert sunlight into useful electrical energy. A conventional solar cell is generally made of thin p-type Si wafer in which the required PN junction is formed by diffusing phosphorus (P) from a suitable phosphorus source on top of wafer generating the n-type emitter layer. A two-dimensional electrode grid pattern, known as a front contact, can be utilized to make a connection to the p-type emitter of silicon. Rear contacts, which can take the shape of a two-dimensional electrode grid pattern, can be made from a conductive paste which is printed and fired on the n-side of the silicon wafer. These contacts are the electrical outlets from the PN junction to the outside load. Such a cell can be utilized either as a bifacial solar cell with the capability of capturing illumination on both sides, or just on one (front) side when an opaque background is provided.

A number of methods have been explored for applying conductive pastes onto a silicon substrate including, evaporation, masking and etching, ink-jet writing and silk screening. In other instances, laser-induced deposition techniques have been investigated where deposition of strips of a conductor material onto a substrate, from a target substrate coated with a continuous layer of the conductive paste, is accomplished by selectively heating the side of the continuous layer facing the substrate with a laser. In general, the trend to smaller line width concomitantly follows two trends: 1) further silver reduction, and 2) reduction of the cell area covered. This automatically increases cell efficiency. The current standard methods, such as screen printing, are limited with regard to their ability to further reduce line width.

Recently, a laser-induced pattern transfer printing process has been discovered for the printing the front side finger lines and bus bars of mono- and multi-crystalline solar cells. Generally, the laser-induced pattern transfer printing process involves a multistep process. First, a transparent polymer substrate having pre-embossed trenches of desired dimensions, in a grid pattern, is prepared. The trenches are then filled with a conductive paste. The conductive paste-filled transparent substrate is then placed over a substrate, such as a silicon wafer, with the paste facing the substrate surface. In general, the transparent substrate and wafer are separated by a distance of, for example, 100-300 μm. The conductive paste-filled transparent substrate is then subjected to laser irradiation. During laser irradiation, the solvent within the paste evaporates, causing shrinkage of the paste. As the paste shrinks, it is released from the trenches due to a resulting over-pressure which accelerates the paste away from the trench and towards the wafer.

While the laser-induced pattern transfer printing process has been found beneficial in many aspects, the process suffers from numerous drawbacks. For example, in some instances, powerful lasers are required. High powered lasers are not optimum for operation of other machine components associated with and in close proximity to the laser. High powered lasers can also cause the release of the paste from the transparent substrate and onto the wafer somewhat uncontrolled. When a paste needs high laser power to release from the transparent substrate, undesirable spreading and/or slumping of the paste on the wafer may occur as well as result in detrimental debris on the wafer surface (i.e., paste on the wafer in locations other than where guided by the trenches of the transparent substrate). The described failures can cause increased shading of the cell by the finger and higher finger line resistivity due to nonuniform line thickness.

### BRIEF DESCRIPTION OF THE DRAWINGS

FIG. 1 is a schematic illustration of an exemplary laser-induced pattern transfer printing process;

FIG. 2 is an illustration of different types of conductive component particulate shapes for use in conductive pastes according to various aspects of the disclosure;

FIG. 3 is an illustration of different types of conductive component particulate mixtures for use in conductive pastes according to various aspects of the disclosure;

FIG. 4 is a graph displaying the reflectance values of conductive pastes in accordance with various aspects of the disclosure, from 800 to 1300 nm;

FIG. 5 shows SEM cross-section (top) and overhead (bottom) images a finger line formed on a silicon wafer via a laser-induced pattern transfer printing process in accordance with FIG. 1 using conductive paste B;

FIG. 6 shows SEM cross-section (top) and overhead (bottom) images a finger line formed on a silicon wafer via a laser-induced pattern transfer printing process in accordance with FIG. 1 using conductive paste A;

FIG. 7 is a graph displaying the reflectance values of conductive pastes in accordance with various aspects of the disclosure, from 800 to 1300 nm, with varying silver particle content; and

FIG. 8 is a graph displaying the reflectance values of conductive pastes in accordance with various aspects of the disclosure, from 800 to 1300 nm, with varying glass component content.

### DETAILED DESCRIPTION

The following description of the embodiments is merely exemplary in nature and is in no way intended to limit the subject matter of the disclosure, their application, or uses.

As used throughout, ranges are used as shorthand for describing each and every value that is within the range. Any value within the range can be selected as the terminus of the range. Unless otherwise specified, all percentages and amounts expressed herein and elsewhere in the specification should be understood to refer to percentages by weight.

For the purposes of this specification and appended claims, unless otherwise indicated, all numbers expressing quantities, percentages or proportions, and other numerical values used in the specification and claims, are to be understood as being modified in all instances by the term “about.” The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent, alternatively ±5 percent, alternatively ±1 percent, alternatively ±0.5 percent, and alternatively ±0.1 percent of the given numeric value provided such a deviation does not alter the end function or result of the value. Accordingly, unless indicated to the contrary, the numerical parameters set forth in this specification and attached claims are approximations that can vary depending upon the desired properties sought to be obtained by the invention.

It is noted that, as used in this specification and the appended claims, the singular forms “a,” “an,” and “the,” include plural references unless expressly and unequivocally limited to one referent. As used herein, the term “include” and its grammatical variants are intended to be non-limiting, such that recitation of items in a list is not to the exclusion of other like items that can be substituted or added to the listed items. For example, as used in this specification and the following claims, the terms “comprise” (as well as forms, derivatives, or variations thereof, such as “comprising” and “comprises”), “include” (as well as forms, derivatives, or variations thereof, such as “including” and “includes”) and “has” (as well as forms, derivatives, or variations thereof, such as “having” and “have”) are inclusive (i.e., open-ended) and do not exclude additional elements or steps. Accordingly, these terms are intended to not only cover the recited element(s) or step(s), but may also include other elements or steps not expressly recited. Furthermore, as used herein, the use of the terms “a” or “an” when used in conjunction with an element may mean “one,” but it is also consistent with the meaning of “one or more,” “at least one,” and “one or more than one.” Therefore, an element preceded by “a” or “an” does not, without more constraints, preclude the existence of additional identical elements.

For the fabrication of higher quality solar cells, the disclosure is directed to conductive pastes for use in the formation of finger lines and/or bus bars on photoabsorbing substrates such as, but not limited to, silicon wafers, cadmium telluride, gallium arsenide, copper indium gallium selenide (CIGSe), copper indium gallium sulfide (CIGS), copper indium selenide (CISe), Copper indium sulfide (CIS), organic semiconductors, etc. More specifically, the disclosure is directed to improved conductive pastes for the formation of conductive lines or strips (linear or non-linear) triangular grids, square grids, hexagonal grids, other single-type polygonal grids, multi-type polygonal grids (that is, a grid made up of a combination of two-different types of polygons), isolated or interconnected shaped islands, and so on, via laser-induced pattern transfer printing processes. Various aspects of the present disclosure are particularly useful for the formation of finger lines and/or bus bars on photoabsorbing substrates.

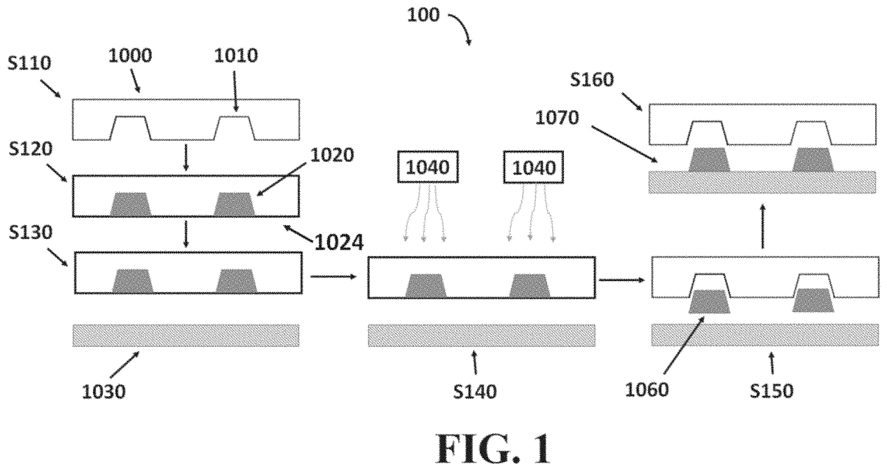

FIG. 1 is a schematic illustration of a laser-induced pattern transfer printing process 100. While the process 100 shows a number of steps, one of skill in the art may appreciate the process 100 may include more or less steps than shown. The process 100 can start at step S110.

In step S110, a transparent substrate or foil 1000 with a plurality of recesses or trenches 1010 is provided. The plurality of recesses or trenches 1010 can be arranged to form a two-dimensional electrode grid pattern on a photoabsorbing substrate. In some instances, the electrode grid pattern can in the form of a plurality of finger lines and/or bus bars. In other instances, the electrode grid pattern can be in the form of a plurality of lines or strips (linear or non-linear), a plurality of one or polygons such as triangles, squares, or hexagons, isolated or interconnected shaped islands, and so on. In FIG. 1, the general cross-sectional shape of the trenches 1010 are that of an isosceles trapezoid. In some instances, the cross-sectional shape trenches 1010 can take the form a square, rectangular, semicircular, semiovoidal, triangular, or any other suitable shape. In some instances, the trenches 1010 can be from about 5 to about 40 μm, alternatively from about 10 to about 30 μm, alternatively from about 15 to about 25 μm, and alternatively about 20 μm, in depth. The width of the trenches 1010, measured at the outermost surface of the substrate 1000, can be from about 10 to about 50 μm, alternatively from about 15 to about 40 μm, alternatively from about 15 to about 30 μm, and alternatively from about 20 to about 30 μm.

In step S120, the trenches 1010 are filled with a conductive paste 1020 to form a conductive paste-filled substrate 1024. The trenches 1010 can filled be with the conductive paste 1020 using any suitable method. In some instances, the trenches 1010 are filled with the conductive paste 1020 via a doctor blading process.

In step S130, the conductive paste-filled substrate 1024 is placed over a photoabsorbing substrate 1030 such that there is gap therebetween. The gap between the conductive paste-filled substrate 1024 and photoabsorbing substrate 1030 can be, for example, from about 100 to about 300 μm.

In step S140, a laser 1040 is used to irradiate the conductive paste-filled substrate 1024. As the laser 1040 irradiates the conductive paste-filled substrate 1024, the transparent substrate 1000 and conductive paste 1020 are heated and solvent is removed from the paste 1020 via evaporation. The laser can be configured to emit light having one or more wavelengths ranging from about 800 nm to about 1300 nm. In some instances, the laser 1040 is a continuous wave IR laser configured to emit at a wavelength of 1064 nm.

In step S150, evaporation of the solvent from the conductive paste 1020 results in the formation of a shrunken paste 1060. The solvent evaporation process creates an overpressure at the interface of the paste 1020 and the trenches 1010 and the paste 1060 releases from the transparent substrate 1000 and is transferred to the photoabsorbing substrate 1030.

In step S160, the final substrate 1070 is formed and the transparent substrate 1000 is removed. The final substrate 1070 can then be subjected to additional processing steps toward the fabrication of a final solar cell product.

In some instances, the process 100 can be repeating at least one time using the final substrate 1070 in step S130 with the solvent-evaporated conductive paste 1060 being placed directly on top of the previously formed two-dimensional electrode grid pattern of the final substrate 1070.

During the production of two-dimensional electrode grid patterns, such as finger lines and/or bus bars, on photoabsorbing substrates using laser-induced pattern transfer printing processes, it has been observed that some conductive pastes require the use of a high-powered laser. The use of a high-powered laser, however, is not optimum for the operation of other machine components associated with and in close proximity to the laser. The use of a high-powered laser can also cause the release of the paste from the transparent substrate and onto a photoabsorbing layer to be somewhat uncontrolled. When a paste requires high laser power to release from the transparent substrate, undesirable spreading and or slumping of the paste on the photoabsorbing layer may occur as well as result on detrimental debris on the photoabsorbing layer surface (i.e., paste on the photoabsorber in locations other than where guided by the trenches of the transparent substrate).

To obviate the need for high powered lasers in pattern transfer printing processes, the inventors have sought to develop conductive pastes which do not require high laser power to achieve solvent evaporation therefrom and resultant transfer of the paste from the transparent substrate onto the photoabsorbing layer. In this endeavor, the inventors have surprisingly found that the use of conductive pastes that minimize reflection of the laser light (that is, light having a wavelength ranging from about 800 to about 1300 nm) during irradiation result in the formation of more uniform finger lines and/or bus bars on photoabsorbing substrates. Unexpectedly there is no linear correlation between reflection and surface area of the silver powder. Specifically, the inventors have found that conductive pastes which exhibit light reflectance values of 50% or less are advantageous. In some instances, conductive pastes for use in laser-induced pattern transfer printing processes exhibiting light reflectance values of 45% or less can be used. In other instances, conductive pastes exhibiting light reflectance values of 40% or less can be used. In yet other instances, conductive pastes exhibiting light reflectance values of 35% or less can be used. In yet other instances, conductive pastes exhibiting light reflectance values of 30% or less can be used. In yet other instances, conductive pastes exhibiting light reflectance values of 25% or less can be used. In yet other instances, conductive pastes exhibiting light reflectance values of 20% or less can be used.

Conductive pastes used in accordance with various aspects of the disclosure can be composed of three primary components: 1) a conductive component, 2) a glass component, and 3) an organic vehicle.

Pastes in accordance with the disclosure can comprise from about 50 to about 90 wt % of the conductive component. In some instances, pastes in accordance with the disclosure can comprise from about 60 to about 90 wt %, alternatively from about 70 to about 90 wt %, alternatively from about 75 to about 90 wt %, and alternatively from about 80 to about 90 wt % of the conductive component.

Pastes in accordance with the disclosure can comprise at least about 1 wt % of the glass component, alternatively at least about 2 wt %, and alternatively at least about 3 wt %, based upon the total weight of the paste. Generally, pastes in accordance with the disclosure comprise no more than about 10 wt %, alternatively no more than about 8 wt %, alternatively no more than about 6 wt %, and alternatively no more than about 5 wt % of the glass component. In some instances, the paste contains about 2 to about 5 wt % of the glass component, alternatively about 2 to about 4 wt %, and alternatively about 2 to about 3 wt % of the glass component of the glass component based upon 100% total weight of the paste.

Pastes in accordance with the disclosure can comprise from about 7 to about 50 wt % of organic vehicle. In some instances, pastes in accordance with the disclosure can comprise from about 7 to about 40 wt %, alternatively from about 7 to about 30 wt %, from about 7 to about 20 wt %, from about 8 to about 15 wt %, and alternatively from about 8 to about 12 wt % of the organic vehicle.

In some instances, one or more additives, that promote and increase adhesion of the paste to the underlying photoabsorbing substrate, may be included in the paste.

The inventors have found that variation of the amount of glass component has little impact on the overall light reflecting properties of a conductive paste. The inventors have also surprisingly found that a drastic reduction in light reflectance can be achieved by careful choice of the type of conductive components used in conductive pastes. Specifically, by choosing conductive components specific physical characteristics such as dimensional irregularity (i.e., angular and/or exhibiting low sphericity), increased surface area, increased surface area-to-volume ratio (i.e., specific surface area), and/or particles exhibiting high polydispersity (i.e., moderately or poorly sorted mixtures of conductive particles), surface roughness or surface porosity, conductive pastes having light reflectance values of 50% or less can achieved. Conductive pastes according to the disclosure having light reflectance values of 50%, when applied as a finger line or bus bar to a photoabsorbing layer, exhibit more uniform dimensional uniformity (i.e., width and height) and form as more uniform (i.e., more linear) lines.

### Conductive Component

The conductive component of the paste generally includes conductive metallic particles. Preferred conductive metallic particles are those which exhibit optimal conductivity and which effectively sinter upon firing, such that they yield electrodes with high conductivity. Conductive metallic particles known in the art suitable for use in forming electrodes are preferred, including, but not limited to, elemental metals, alloys, mixtures of at least two metals, mixtures of at least two alloys or mixtures of at least one metal with at least one alloy. Metals which may be employed as the metallic particles include at least one of silver, copper, gold, aluminum, nickel, platinum, palladium, molybdenum, and mixtures or alloys thereof. In a preferred embodiment, the metallic particles are silver. The silver particles may be present as elemental silver, one or more silver derivatives, or mixtures thereof. Silver powders may vary based on the production method, purity, particle size, particle shape, apparent density, conductivity, oxygen level, color and flow rate.

In some instances, metallic particles at least partially coated with another metal, which may be referred to a core-shell particle, can be used. When core-shell particles are used, each of the core can be made of a metal or alloy such as, but not limited to silver, gold, platinum, palladium, copper, iron, aluminum, zinc, nickel, brass or bronze. Broadly, a core-shell particle will have a less conductive core covered by a more conductive coating or shell. Alternately, a less noble metal core is covered by more noble metal coating or shell. Ag coated Cu or Ag coated Cu alloys, or Ag coated Ni or Ag coated Ni alloys are good examples. They offer cost benefit as well as better leach resistance than Ag particles. Moreover, more noble metal coating improves the oxidation resistance of the less noble metal. In some instances, the core of a core-shell particle is envisioned to be made of a composition selected from the group consisting of nickel, nickel alloys, copper, copper alloys, non-noble transition metals, alloys of non-noble transition metals, polymers, silica, alumina, glass, graphite and combinations thereof. Single-metal particles can be envisioned, indirectly in the case where the core and shell are the same metal. In particular, the core-shell particles of the invention may be silver coated nickel particles, silver coated copper particles, silver coated polymer particles, silver coated silica particles, silver coated alumina particles, silver coated glass particles, silver coated graphite particles, gold coated nickel particles, gold coated copper particles, gold coated polymer particles, gold coated silica particles, gold coated alumina particles, gold coated glass particles, gold coated graphite particles, platinum coated nickel particles, platinum coated copper particles, platinum coated polymer particles, platinum coated silica particles, platinum coated alumina particles, platinum coated glass particles, platinum coated graphite particles, palladium coated nickel particles, palladium coated copper particles, palladium coated polymer particles, palladium coated silica particles, palladium coated alumina particles, palladium coated glass particles, palladium coated graphite particles, and combinations thereof. In a preferred embodiment, the core is copper and the shell is silver.

The conductive metallic particles can exhibit a variety of general shapes, surfaces, sizes, surface area to volume ratios, oxygen content and oxide layers. Some examples of general shapes include, but are not limited to, round or spherical, angular, irregular, and elongated (rod or needle like). Silver particles may also be present as a combination of particles of different shapes, sizes and/or surface area to volume ratios.

In accordance with various aspects of the disclosure, the conductive particles of the paste are irregularly shaped, however, the particle size may be approximately represented as the diameter of the “equivalent sphere” which would give the same measurement result. Typically, particles in any given sample of conductive particles do not exist in a single size, but are distributed in a range of sizes, i.e., a particle size distribution. One parameter characterizing particle size distribution is D₅₀. D₅₀ is the median diameter or the medium value of the particle size distribution. It is the value of the particle diameter at 50% in the cumulative distribution. Other parameters of particle size distribution are D₁₀, which represents the particle diameter corresponding to 10% cumulative (from 0 to 100%) undersize particle size distribution, and D₉₀, which represents the particle diameter corresponding to 90% cumulative (from 0 to 100%) undersize particle size distribution. Particle size distribution may be measured via laser diffraction, dynamic light scattering, imaging, electrophoretic light scattering, or any other methods known to one skilled in the art. In a preferred embodiment, laser diffraction is used.

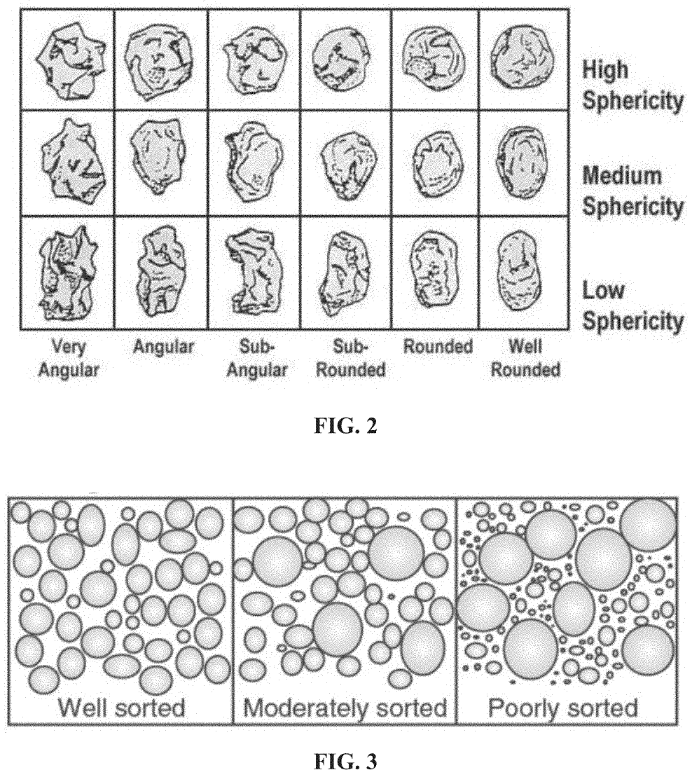

In accordance with various aspects of the disclosure, the conductive particles can have a generally spherical shape. In some instances, the conductive particles may exhibit low to high angularity, a regular or irregular shape, or any combination thereof. In some instances, a combination of conductive particles with uniform shape (i.e., shapes in which the ratios relating the length, the width and the thickness approximate to 1) and less uniform shape may be used. In accordance with various aspects of the disclosure, the low uniformity of the conductive particles can be described in terms of one or both of roundness and sphericity. FIG. 2 is a schematic illustration showing particles along an angularity gradient and having either low or high sphericity. Sphericity and structure of the surface (i.e. rough, smooth, corrugated) influence the surface area and therefore the reflectance for incoming beams for a single particle.

In addition to, or as an alternative to, using conductive particles having one or more of a generally spherical shape, a uniform angularity characteristic (that is, conductive particles sharing a common low to high angularity) and/or a uniform shape characteristic (that is, conductive particles sharing a common regular or irregular shape), conductive components having particles with varying dimensions can be used to fabricate conductive pastes in accordance with various aspects of the present disclosure. FIG. 3 is a schematic illustration of different mixtures of conductive particles. As shown, a mixture of conductive particles having relatively similar dimensions can be considered well sorted, a mixture of conductive particles having only 2 to 3 different particle sizes can be considered moderately sorted, and a mixture of conductive particles having more than three different particle sizes can be considered poorly sorted. In addition to the surface area of the particles, the spacing between the particles plays a role for reflecting light. The space between particles is ruled by packing of the particles in a volume which is influenced by a particle sizes. In general, the different particle sizes are causing a different packing density in a volume. Monomodal distributions will have less packing density and therefore more spacing between particles. On the other hand, a multimodal distribution causes higher packing density. Therefore, the packing density will influence the reflectance via the spacing between the particles.

A way to describe the complex interaction between the incoming light beam and the particles in the bulk material can be done by two main parameters responsible for reflection or distinction of incoming light: 1) the packing density of the particles in the bulk material, and 2) the surface area of a packed volume of the conductive particles, expressed by: SA/tap density ((m²/g/(g/m³), or m⁻¹).

### Glass Component

The paste includes a glass component that allows the conductive component to sufficiently adhere to the underlying substrate and make electrical contact therewith when fired. The glass component may also help to control the sintering of the conductive particles during firing, thereby improving electrical conductivity and adhesion to the substrate. In one embodiment, one or more glass frits may be used. The glass frit may be substantially amorphous, or may incorporate partially crystalline phases or compounds. The glass frit may include a variety of oxides or compounds known to one skilled in the art. For example, silicon, boron, bismuth, zinc, tellurium, manganese, copper, lead, or chromium compounds (e.g., oxides) may be used. Other glass matrix formers or modifiers, such as germanium oxide, phosphorous oxide, vanadium oxide, tungsten oxide, molybdenum oxides, niobium oxide, tin oxide, indium oxide, other alkaline and alkaline earth metal oxides (such as Na, K, Li, Cs, Ca, Sr, Ba, and Mg), intermediates (such as Al, Ti, and Zr), and rare earth oxides (such as La₂O₃ and cerium oxides) may also be included in the glass frit.

The glass frit(s) may be substantially lead free (e.g., contains less than about 5 wt %, such as less than about 4 wt %, less than about 3 wt %, less than about 2 wt %, less than about 1 wt %, less than about 0.5 wt %, less than about 0.1 wt %, or less than about 0.05 wt % or less than about 0.01 wt %) of lead. In a preferred embodiment, the glass frit is lead-free, i.e., without any intentionally added lead or lead compound and having no more than trace amounts of lead.

The glass frits described herein can be made by any process known in the art, including, but not limited to, mixing appropriate amounts of powders of the individual ingredients, heating the powder mixture in air or in an oxygen-containing atmosphere to form a melt, quenching the melt, grinding and ball milling the quenched material and screening the milled material to provide a powder with the desired particle size. For example, glass frit components, in powder form, may be mixed together in a V-comb blender. The mixture is heated to around 800-1300° C. (depending on the materials) for about 30-60 minutes. The glass is then quenched, taking on a sand-like consistency. This coarse glass powder is then milled, such as in a ball mill or jet mill, until a fine powder results. Typically, the glass frit powder is milled to an average particle size of from about 0.01 to about 10 μm such as from about 0.1 to about 5 μm.

### Organic Vehicle

The pastes further comprise an organic vehicle. Preferred organic vehicles in the context of the invention are solutions, emulsions or dispersions based on one or more solvents, preferably organic solvent(s), which ensure that the components of the paste are present in a dissolved, emulsified or dispersed form. Preferred organic vehicles are those which provide optimal stability of the components of the paste and endow the paste with a viscosity allowing for effective printability.

In some instances, the organic vehicle comprises one or more organic solvents, and optionally one or more of 1) a binder (e.g., a polymer or resin), 2) a surfactant (i.e., a wetting agent) and 3) a thixotropic agent. For example, in one embodiment, the organic vehicle comprises one or more binders in an organic solvent. In some instances, the organic vehicle comprises from about 60 to about 90 wt % organic solvent. In other instances, the organic vehicle comprises from about 70 to about 85 wt %, and alternatively from about 75 to about 85 wt % organic solvent. (b) up to about 15 wt % of a binder; (c) up to about 4 wt % of a thixotropic agent; and (d) up to about 2 wt % of a wetting agent. The use of more than one solvent, binder, thixotrope, and/or wetting agent is also envisioned.

Preferred binders in the context of the invention are those which contribute to the formation of a paste with favorable stability, printability, viscosity and sintering properties. All binders which are known in the art, and which are considered suitable in the context of this invention, may be employed as the binder in the organic vehicle. Preferred binders (which often fall within the category termed “resins”) are polymeric binders, monomeric binders, and binders which are a combination of polymers and monomers. Polymeric binders can also be copolymers wherein at least two different monomeric units are contained in a single molecule. Preferred polymeric binders are those which carry functional groups in the polymer main chain, those which carry functional groups off of the main chain and those which carry functional groups both within the main chain and off of the main chain. Preferred polymers carrying functional groups in the main chain are for example polyesters, substituted polyesters, polycarbonates, substituted polycarbonates, polymers which carry cyclic groups in the main chain, poly-sugars, substituted poly-sugars, polyurethanes, substituted polyurethanes, polyamides, substituted polyamides, phenolic resins, substituted phenolic resins, copolymers of the monomers of one or more of the preceding polymers, optionally with other co-monomers, or a combination of at least two thereof. According to one embodiment, the binder may be polyvinyl butyral or polyethylene. Preferred polymers which carry cyclic groups in the main chain are, for example, poly(vinyl butyrate) (PVB) and its derivatives and poly-terpineol and its derivatives or mixtures thereof. Preferred poly-sugars are for example cellulose and alkyl derivatives thereof, preferably methyl cellulose, ethyl cellulose, hydroxyethyl cellulose, propyl cellulose, hydroxypropyl cellulose, butyl cellulose and their derivatives and mixtures of at least two thereof. Other preferred polymers are cellulose ester resins, e.g., cellulose acetate propionate, cellulose acetate butyrate, and any combinations thereof. Preferred polymers which carry functional groups off of the main polymer chain are those which carry amide groups, those which carry acid and/or ester groups, often called acrylic resins, or polymers which carry a combination of aforementioned functional groups, or a combination thereof. Preferred polymers which carry amide groups off of the main chain are for example polyvinyl pyrrolidone (PVP) and its derivatives. Preferred polymers which carry acid and/or ester groups off of the main chain are for example polyacrylic acid and its derivatives, polymethacrylate (PMA) and its derivatives or polymethylmethacrylate (PMMA) and its derivatives, or a mixture thereof. Preferred monomeric binders are ethylene glycol based monomers, terpineol resins or rosin derivatives, or a mixture thereof. Preferred monomeric binders based on ethylene glycol are those with ether groups, ester groups or those with an ether group and an ester group, preferred ether groups being methyl, ethyl, propyl, butyl, pentyl, hexyl, and higher alkyl ethers, the preferred ester group being acetate and its alkyl derivatives, preferably ethylene glycol monobutylether monoacetate or a mixture thereof.

Acrylic-based resins, and their derivatives and mixtures thereof with other binders, are preferred binders in the context of the invention. Suitable acrylic resins include, but are not limited to, isobutyl methacrylate, n-butyl methacrylate, and combinations thereof. Acrylic resins having a high molecular weight, about 130,000-150,000, are suitable. The binder may be present in an amount of at least about 0.5 wt %, preferably at least about 1 wt %, more preferably at least about 2 wt %, and most preferably at least about 3 wt %, based upon 100% total weight of the paste. At the same time, the binder is preferably present in an amount of no more than about 10 wt %, preferably no more than about 8 wt %, and most preferably no more than about 6 wt %, based upon 100% total weight of the paste. In a most preferred embodiment, the paste includes about 3-5 wt % of binder.

Preferred solvents are those which contribute to favorable viscosity, printability, paste stability and sintering characteristics. All solvents which are known in the art, and which are considered suitable in the context of this invention, may be employed as the solvent in the organic vehicle. Preferred solvents are those which exist as a liquid under standard ambient temperature and pressure (SATP) (298.15 K, 25° C., 77° F.), 100 kPa (14.504 psi, 0.986 atm), preferably those with a boiling point above about 90° C. and a melting point above about −20° C. Preferred solvents are polar or non-polar, protic or aprotic, aromatic or non-aromatic. Preferred solvents are mono-alcohols, di-alcohols, poly-alcohols, mono-esters, di-esters, poly-esters, mono-ethers, di-ethers, poly-ethers, solvents which comprise at least one or more of these categories of functional group, optionally comprising other categories of functional group, preferably cyclic groups, aromatic groups, unsaturated bonds, alcohol groups with one or more O atoms replaced by heteroatoms, ether groups with one or more O atoms replaced by heteroatoms, esters groups with one or more O atoms replaced by heteroatoms, and mixtures of two or more of the aforementioned solvents. Preferred esters in this context are di-alkyl esters of adipic acid, preferred alkyl constituents being methyl, ethyl, propyl, butyl, pentyl, hexyl and higher alkyl groups or combinations of two different such alkyl groups, preferably dimethyladipate, and mixtures of two or more adipate esters. Preferred ethers in this context are diethers, preferably dialkyl ethers of ethylene glycol, preferred alkyl constituents being methyl, ethyl, propyl, butyl, pentyl, hexyl and higher alkyl groups or combinations of two different such alkyl groups, and mixtures of two diethers. Preferred alcohols in this context are primary, secondary and tertiary alcohols, preferably tertiary alcohols, terpineol and its derivatives being preferred, or a mixture of two or more alcohols.

Widely used solvents include terpenes such as alpha- or beta-terpineol or higher boiling alcohols such as Dowanol® (diethylene glycol monoethyl ether), or mixtures thereof with other solvents such as butyl Carbitol® (diethylene glycol monobutyl ether); dibutyl Carbitol® (diethylene glycol dibutyl ether), butyl Carbitol® acetate (diethylene glycol monobutyl ether acetate), hexylene glycol, Texanol® (2,2,4-trimethyl-1,3-pentanediol monoisobutyrate), as well as other alcohol esters, kerosene, and dibutyl phthalate. The vehicle can contain organometallic compounds, for example those based on nickel, phosphorus or silver, to modify the contact. N-DIFFUSOL® is a stabilized liquid preparation containing an n-type diffusant with a diffusion coefficient similar to that of elemental phosphorus. Various combinations of these and other solvents can be formulated to obtain the desired viscosity and volatility requirements for each application. Other dispersants, surfactants and rheology modifiers, which are commonly used in thick film paste formulations, may be included. Commercial examples of such products include those sold under any of the following trademarks: Texanol® (Eastman Chemical Company, Kingsport, Tenn.); Dowanol® and Carbitol® (Dow Chemical Co., Midland, Mich.); Triton® (Union Carbide Division of Dow Chemical Co., Midland, Mich.), Thixatrol® (Elementis Company, Hightstown N.J.), and Diffusol® (Transene Co. Inc., Danvers, Mass.).

The organic vehicle may also comprise one or more surfactants and/or additives. Preferred surfactants are those which contribute to the formation of a paste with favorable stability, printability, viscosity and sintering properties. All surfactants which are known in the art, and which are considered suitable in the context of this invention, may be employed as the surfactant in the organic vehicle. Preferred surfactants are those based on linear chains, branched chains, aromatic chains, fluorinated chains, siloxane chains, polyether chains and combinations thereof. Preferred surfactants include, but are not limited to, single chained, double chained or poly chained polymers. Preferred surfactants may have non-ionic, anionic, cationic, amphiphilic, or zwitterionic heads. Preferred surfactants may be polymeric and monomeric or a mixture thereof. Preferred surfactants may have pigment affinic groups, preferably hydroxyfunctional carboxylic acid esters with pigment affinic groups (e.g., DISPERBYK®-108, manufactured by BYK USA, Inc.), polycarboxylic acid salt of polyamine amides (e.g., ANTI-TERRA® 204, manufactured by BYK USA, Inc.), acrylate copolymers with pigment affinic groups (e.g., DISPERBYK®-116, manufactured by BYK USA, Inc.), modified polyethers with pigment affinic groups (e.g., TEGO® DISPERS 655, manufactured by Evonik Tego Chemie GmbH), fatty alkyl amine (e.g., Duomeen® TDO, manufactured by AkzoNobel N.V.), or other surfactants with groups of high pigment affinity (e.g., TEGO® DISPERS 662 C, manufactured by Evonik Tego Chemie GmbH). Other preferred polymers not in the above list include, but are not limited to, polyethylene oxide, polyethylene glycol and its derivatives, and alkyl carboxylic acids and their derivatives or salts, or mixtures thereof. The preferred polyethylene glycol derivative is poly(ethyleneglycol)acetic acid. Preferred alkyl carboxylic acids are those with fully saturated and those with singly or poly unsaturated alkyl chains or mixtures thereof. Preferred carboxylic acids with saturated alkyl chains are those with alkyl chains lengths in a range from about 8 to about 20 carbon atoms, preferably C₉H₁₉COOH (capric acid), C₁₁H₂₃COOH (Lauric acid), C₁₃H₂₇COOH (myristic acid) C₁₅H₃₁COOH (palmitic acid), C₁₇H₃₅COOH (stearic acid), or salts or mixtures thereof. Preferred carboxylic acids with unsaturated alkyl chains are C₁₈H₃₄O₂ (oleic acid) and C₁₈H₃₂O₂ (linoleic acid). A preferred monomeric surfactant is benzotriazole and its derivatives. If present, the surfactant may be at least about 0.01 wt %, based upon 100% total weight of the organic vehicle. At the same time, the surfactant is preferably no more than about 10 wt %, preferably no more than about 8 wt %, more preferably no more than about 6 wt %, more preferably no more than about 4 wt %, and most preferably no more than about 2 wt %, based upon 100% total weight of the organic vehicle.

Preferred additives in the organic vehicle are those materials which are distinct from the aforementioned components and which contribute to favorable properties of the paste, such as advantageous viscosity, printability, stability and sintering characteristics. Additives known in the art, and which are considered suitable in the context of the invention, may be used. Preferred additives include, but are not limited to, thixotropic agents, viscosity regulators, stabilizing agents, inorganic additives, thickeners, emulsifiers, dispersants and pH regulators. Preferred thixotropic agents include, but are not limited to, carboxylic acid derivatives, preferably fatty acid derivatives or combinations thereof. Preferred fatty acid derivatives include, but are not limited to, C₉H₁₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid), C₁₈H₃₄O₂ (oleic acid), C₁₈H₃₂O₂ (linoleic acid) and combinations thereof. A preferred combination comprising fatty acids in this context is castor oil. A thixotrope is not always necessary because the solvent coupled with the shear thinning inherent in any suspension may alone be suitable in this regard. Furthermore, wetting agents may be employed such as fatty acid esters, e.g., N-tallow-1,3-diaminopropane dioleate; N-tallow trimethylene diamine diacetate; N-coco trimethylene diamine, beta diamines; N-oleyl trimethylene diamine; N-tallow trimethylene diamine; N-tallow trimethylene diamine dioleate, and combinations thereof.

### Other Additives

In some instances, one or more additives that promote and increase adhesion to the underlying substrate may be included in the paste (hereinafter, the “adhesion promoting additive”). In a preferred embodiment, at least one adhesion promoting additive is used. For example, the adhesion promoting additive(s) may be selected from cuprous oxide, titanium oxide, zirconium oxide, titanium carbide, zirconium resinate (e.g., Zr carboxylate), amorphous boron, aluminum silicate, lithium carbonate, lithium phosphate, lithium tungstate, bismuth oxide, aluminum oxide, cerium oxide, zinc oxide, magnesium oxide, silicon dioxide, ruthenium oxide, tellurium oxide, and combinations thereof.

In some instances, up to about 30 wt % of other (i.e., inorganic) additives, preferably up to about 25 wt % and more preferably up to about 20 wt %, may be included as needed. Trivalent additives, i.e., dopants, such as B, Al, Ga, In, Tl, Sc, Y, La, Bi, transition elements such as Mn, Cr, Co, Rh, Ir, Os, Fe and rare earth elements such as Ce, Pr, Nd, Gd, Tb, Yb may be used in the form of metal or alloy or organo-metallic or oxides or silicides or borides or nitrides. Other transition metals capable of exhibiting a trivalent (III) state can be used. It is also envisioned to add cobalt, copper, zinc, and/or iron either in a metallic or organometallic or oxide or other inorganic compounds such as pigments containing these elements to improve the electrical and adhesion properties.

Boron, indium and gallium and/or compounds thereof, for example, InSe, In₂Se₃, GaSe, Ga₂Se₃ can be added to the paste in a variety of ways to reduce the resistance of the front contacts for p+ type emitters. In a preferred embodiment, such additives are used with the goal of eliminating aluminum from the contact. For example, certain glasses can be modified with boron-oxide in the form of a powdered or fritted oxide, or boron can be added to the paste by way of boride or other organoboron compounds. It can also be added as boron-silicide to the paste. Further, silicides of the other metals in this paragraph can be useful.

Other additives such as fine silicon or carbon powder, or both, and aluminum alloys such as Al-alloys such as Al—Si, for example 0.01 to 10 wt %, can be added to control the reactivity of the metal component with silicon. For example, these fine silicon or carbon powder can be added to the front contact silver paste to control the silver reduction and precipitation reaction. The silver precipitation at the Ag/Si interface or in the bulk glass, for the silver pastes in both front contacts and rear contacts, can also be controlled by adjusting the firing atmosphere (e.g., firing in flowing N₂ or N₂/H₂/H₂O mixtures). About 0.01 wt % to about 10 wt % of fine particles of low melting metal additives (i.e., elemental metallic additives as distinct from metal oxides) such as Pb, Bi, In, Ga, Sn, and Zn and alloys of each with at least one other metal can be added to provide a contact at a lower temperature, or to widen the firing window. Zinc is the preferred metal additive, and a zinc-silver alloy is most preferred for the front contact.

Aluminum can be used to form a low resistance contact with p-type emitter. However, Al by itself cannot be used since it will cause shunting at PN junction and degrades the cell efficiency. It also decreases the bulk resistivity of the paste which strongly degrades the series resistance of the cell in such grid pattern configuration. It is preferred to have Al and other metals/alloys of at least 99% purity to maximize solar cell electrical performance. In place of pure Al, the aluminum may be provided by alloys such as Al—Si, Al—Ag and Al—Zn. The Al—Si eutectic (12.2 atomic % Si and 87.8 atomic % Al) may be used. Generally, the Al—Si alloy with 0.01 to 30 atomic % Si may be used. Al—B alloys may be used, for example 68 atomic % B and 32 atomic % Al. Al—Ag alloys may be used alternately, having 0.01-50 atomic % Ag, preferably 0.01-20 atomic % Ag. Al—Zn alloys may be used. In particular, Al—Zn alloys having 16.5 atomic % Zn, or 59 atomic % Zn or 88.7 atomic % Zn are useful. More generally, Al—Zn alloys having 0.01-30 atomic % Zn or 40-70 atomic % Zn or 80-90 atomic % Zn are useful.

More than one paste can be used as a coating on the silicon wafer. Indeed, an embodiment of the invention is any solar cell herein having a second paste layer present at least partially coextensive with the paste on the p-side, the second paste having high conductivity or having low bulk resistivity, such as a bulk resistivity from 1×10⁻⁶ to 4×10⁻⁶ Ohm-cm.

The inorganic additives described herein may be provided in one or more of several physical and chemical forms. Broadly, powders, flakes, salts, oxides, glasses, colloids, and organometallics of the inorganic additives are suitable. In some instances, powder sizes can range from about 0.1 to about 40 microns, and alternatively up to about 10 microns. In some instance, inorganic additives can be provided in the form of ionic salts, such as the halides, carbonates, hydroxides, phosphates, nitrates, sulfates, and sulfites, of the metal of interest. Organometallic compounds can also be used, including, without limitation, the acetates, formates, carboxylates, phthalates, isophthalates, terephthalates, fumarates, salicylates, tartrates, gluconates, or chelates such as those with ethylenediamine (en) or ethylenediamine tetraacetic acid (EDTA). Other appropriate powders, salts, oxides, glasses, colloids, and organometallics containing at least one of the relevant metals known to those skilled in the art may also be used.

When incorporated into a conductive paste, the paste preferably comprises at least about 0.1 wt %, preferably at least about 0.5 wt %, of an adhesion promoting additive, based upon 100% total weight of the paste. At the same time, the paste preferably comprises no more than about 5 wt %, and preferably no more than about 4 wt %, of the adhesion promoting additive. In one preferred embodiment, the paste comprises about 0.5-2 wt %, preferably about 0.5-1 wt %, of adhesion promoting additive(s). In another preferred embodiment, the paste comprises about 0.5-5 wt % of an adhesion promoting additive.

### Paste Preparation

Conductive paste in accordance with various aspects of the disclosure can be conveniently prepared on a three-roll mill. The amount and type of carrier utilized are determined mainly by the final desired formulation viscosity, fineness of grind of the paste, and the desired wet print thickness. In preparing compositions according to the disclosure, the particulate inorganic solids are mixed with the vehicle and dispersed with suitable equipment, such as a three-roll mill, to form a suspension, resulting in a composition for which the viscosity will be in the range of about 100 to about 500 kcps, preferably about 300 to about 400 kcps, at a shear rate of 9.6 sec⁻¹ as determined on a Brookfield viscometer HBT, spindle 14, measured at 25° C.

### EXAMPLES

Reflectance Measurements. Reflectance measurements were carried out a Newport Oriel Instruments IQE (Internal Quantum Efficiency), or “IQE 200”, measurement tool. Incident light was passed through a monochromator that separated the light into discrete wavelengths in increments of 10 nm and focused on the sample of interest which is part of a white integrating sphere. To obtain reflectance curves, paste samples with different silver loadings were printed on 1 in.×1 in. square using a 325 wires/0.9 μm diameter mesh, 22 μm mesh thickness, 15 μm EOM (Emulsion-over mesh) standard screen on a textured mono-crystalline solar wafer with 80 nm SiNx anti-reflection coating. All pastes with varying silver and glass percentages were printed the same way. Reflectance was measured as printed (i.e., without subsequent drying or firing) to mimic the state of the paste when subjected to laser irradiation during a pattern transfer printing process. Reflectance measurements are obtained in the 800-1300 nm range, which is all IR and encompasses the wavelength of lasers generally used in a pattern transfer printing process (1064 nm).

Preparation of Silver Pastes. To determine the effect of conductive component physical properties (i.e., shape, specific surface area, etc.) on the reflectance properties and printability of conductive pastes, two conductive pastes were prepared. The silver particles of Paste A exhibited an average SSA of 0.44 m²/g, an SA/tap density value of 9.2 m⁻¹, a D₁₀ of about 1.0 μm, a D₅₀ of about 1.7 μm, and a D₉₀ of about 2.85 μm. The silver particles of Paste B exhibited an average SSA of 0.29 m²/g, an SA/tap density value of 6.1 m¹, a D₁₀ of about 0.68 μm, a D₅₀ of about 1.36 μm, and a D₉₀ of about 1.92 μm. Both Pastes A and B were made with the same glass component and the same organic vehicle. Additionally, unless otherwise specified, both pastes A and B were made to have 88-90 wt % (for example, 88.6 wt %) of silver particles, 0 or 3 wt % glass component, and 9 wt % organic vehicle. Paste A exhibited a viscosity of 214 kcps and Paste B exhibited a viscosity of 179 kcps. To measure the viscosity of the pastes, a Brookfield HBDV-III Digital Rheometer equipped with a CP-44Y sample cup and a #51 cone was used. The temperatures of the pastes were maintained at 25° C. using a TC-502 circulating temperature bath. The measurement gap was set at 0.026 mm with a sample volume of approximately 0.5 ml. The pastes were allowed to equilibrate for two minutes, and then a constant rotational speed of 1.0 rpm was applied for one minute. After this interval, the viscosities of the pastes were determined.

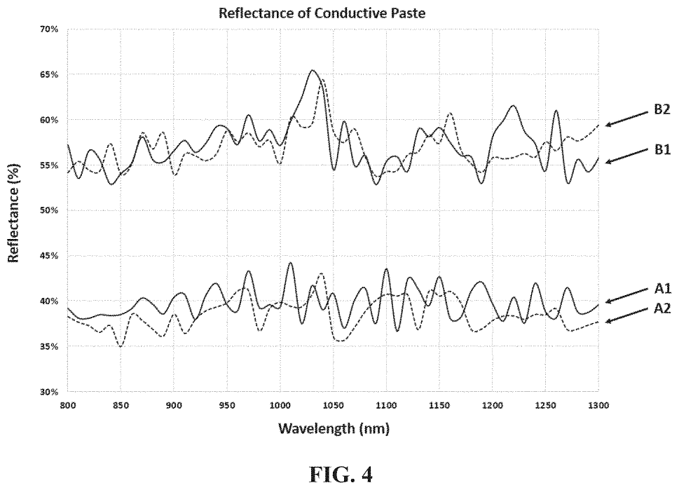

FIG. 4 is a graph illustrating the reflectance values of conductive pastes A and B from 800 to 1300 nm. Line A1 corresponds to reflectance values for conductive paste A with 2 wt % glass component. Line A2 corresponds to reflectance values for conductive paste A with 0 wt % glass component. Line B1 corresponds to reflectance values for conductive paste B with 2 wt % glass component. Line B2 corresponds to reflectance values for conductive paste B with 0 wt % glass component. As can be seen conductive paste A exhibited reflectance values ranging between about 35 and about 45% along the 800-1300 wavelength spectrum, regardless of the presence of glass component within the conductive paste. Conductive paste B, on the other hand, exhibited noticeably larger reflectance values ranging between about 53% and 66% along the 800-1300 wavelength spectrum. The data of FIG. 4 indicates that the silver particles in paste A minimize reflection of light during laser irradiation better than the silver particles in paste B.

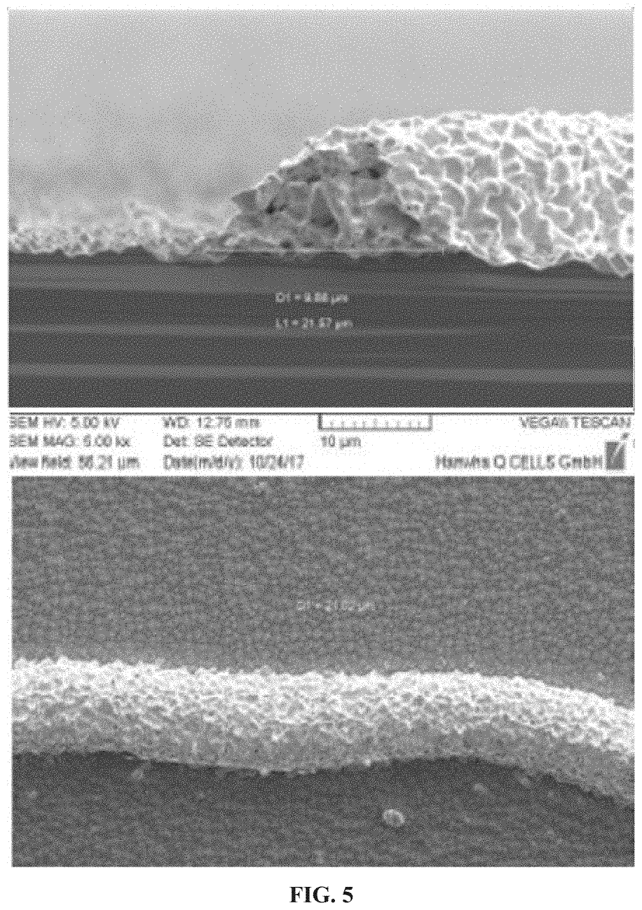

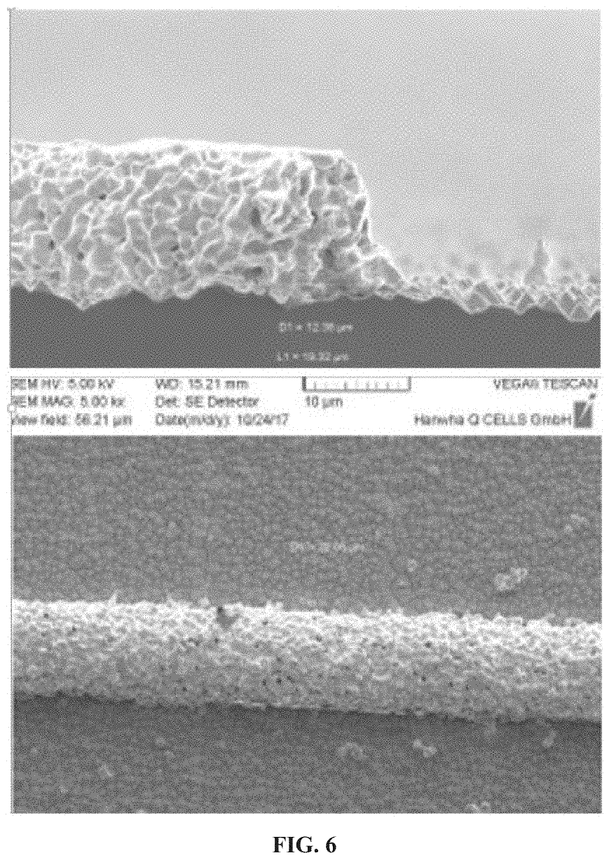

FIG. 5 shows SEM cross-section (top) and overhead (bottom) images a finger line formed on a silicon wafer via a laser-induced pattern transfer printing process in accordance with FIG. 1 using conductive paste B. FIG. 6 shows SEM cross-section (top) and overhead (bottom) images a finger line formed on a silicon wafer via a laser-induced pattern transfer printing process in accordance with FIG. 1 using conductive paste A. In both instances, finger line formation was conducted using the same laser-induced pattern transfer printing process parameters and using transparent substrates having the same trench dimensions. The finger lines formed from conductive Paste B exhibit base widths of about 21.6 μm and heights of about 9.5 μm. The finger lines formed from conductive Paste A, on the other hand, exhibit base widths of about 19.2 μm and heights of about 12.4 μm. This data indicates that interaction paste-laser and finally reflectance values influence laydown pattern of finger. The use of conductive pastes having reflectance values of more than 50%, such as conductive Paste B, exhibit slumping and spreading effects, resulting in finger lines which are shorter and wider than that of finger lines formed from conductive pastes having reflectance values of 50% or less, such as conductive Paste A. Furthermore, conductive pastes having reflectance values of more than 50%, such as conductive Paste B, are shown to deposit on a substrate with low line linearity whereas conductive pastes having reflectance values of 50% or less, such as conductive Paste A, are shown to deposit on a substrate as a highly linear line.

Table 2 compares the solar cell efficiency (Eta), short circuit current density (J_{SC}), open-current voltage (V_{OC}), fill factor (FF), and grid resistance of solar cells having finger lines produced using conductive Pastes A and B. In addition to the improved printability evidenced in the SEM images of FIG. 6, conductive Paste A was found have superior properties relative to conductive paste B. Specifically, the use of conductive Paste A resulted in solar cells exhibiting higher average Eta, J_{sc}, V_{OC}, and FF values compared to conductive Paste B, while also exhibiting a noticeable decrease in grid resistance.

TABLE 2

| | | | | | Grid Res |
|---|---|---|---|---|---|
| | Eta | J_{SC} | V_{OC} | FF | Front_Max |
| Paste | (%) | (mA/cm²) | (V) | (%) | (mΩ) |
| A | 21.5748 | 40.2253 | 0.67103 | 79.8266 | 74.5383 |
| B | 21.4278 | 40.0880 | 0.67017 | 79.7390 | 76.6026 |

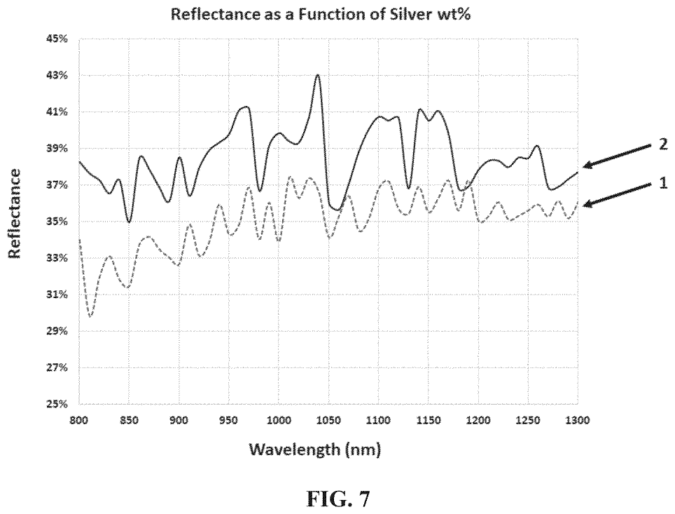

Reflectance as a Function of Silver Content. FIG. 7 is a graph displaying the reflectance values of three conductive pastes, with varying amounts of Silver A, from 800 to 1300 nm. Paste 1 had 80 wt % Silver A, and Paste 2 has 89 wt % Silver A. Each paste comprised 2 wt % glass component and the balance of the same organic vehicle (that is 9 wt % in Paste 1 and 18 wt % in Paste 2). As can be seen, reflectance values decrease along the majority of the 800-1300 wavelength spectrum as the silver content is decreased from 89 wt % to 80 wt %.

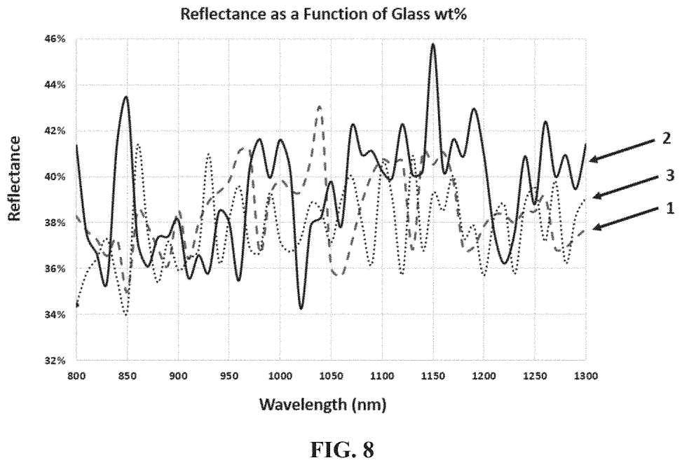

Reflectance as a Function of Glass Component Content. FIG. 8 is a graph displaying the reflectance values of three conductive pastes, with varying amounts glass component, from 800 to 1300 nm. Paste 1 had 2 wt % glass component, Paste 2 had 3 wt % glass component, and Paste 3 has 5 wt % glass component. Each of the pastes comprised 89 wt % Silver A and the balance of the same organic vehicle. As can be seen each paste exhibited similar reflectance values along the 800-1300 wavelength spectrum.

Although the invention and its objects, features and advantages have been described in detail, other embodiments are encompassed by the invention. All references cited herein are incorporate by reference in their entireties. Finally, those skilled in the art should appreciate that they can readily use the disclosed conception and specific embodiments as a basis for designing or modifying other structures for carrying out the same purposes of the invention without departing from the scope of the invention as defined by the appended claims.

What is claimed is:

1. A conductive paste for use in a laser-induced pattern transfer printing process, the conductive paste comprising:
a conductive component;
a glass component; and
an inorganic vehicle,
wherein the conductive paste exhibits a light reflectance of no more than 50% across a light wavelength range of about 800 to about 1300 nm.

2. The conductive paste of claim 1, wherein the conductive component is about 50 to about 90 wt % of the conductive paste.

3. The conductive paste of claim 1, wherein the conductive component is about 80 to about 90 wt % of the conductive paste.

4. The conductive paste of claim 1, wherein the glass component is about 1 to about 10 wt % of the conductive paste.

5. The conductive paste of claim 1, wherein the glass component is about 1 to about 10 wt % of the conductive paste.

6. The conductive paste of claim 1, wherein the glass component is about 2 to about 5 wt % of the conductive paste.

7. The conductive paste of claim 1, wherein the organic vehicle is about 7 to about 50 wt % of the conductive paste.

8. The conductive paste of claim 1, wherein the organic vehicle is about 8 to about 15 wt % of the conductive paste.

9. The conductive paste of claim 1, wherein the conductive component comprises metallic particles.

10. The conductive paste of claim 9, wherein the metallic particles are silver particles.

11. The conductive paste of claim 9, wherein the metallic particles are core-shell particles.

12. The conductive paste of claim 1, wherein the conductive component comprises a mixture of at least two different conductive particles.

13. A process for laser-induced pattern transfer printing, the process comprising:
providing a first substrate comprising a recessed surface and a conductive paste according to claim 1 disposed in the recessed surface;
orienting the recessed surface of the first substrate toward a second substrate;
irradiating the conductive paste with a laser, the laser configured to emit light having a wavelength between about 800 and about 1300 nm; and
transferring the irradiate conductive paste from the first substrate to a surface of the second substrate.

14. The process of claim 13, wherein the recessed surface has a depth of from about 5 to about 40 μm.

15. The process of claim 13, wherein the recessed surface has a depth of from about 15 to about 25 μm.

16. The process of claim 13, wherein the recessed surface has a width of from about 10 to about 50 μm.

17. The process of claim 13, wherein the recessed surface has a width of from about 20 to about 30 μm.

18. The process of claim 13, wherein the recessed surface has a cross-sectional shape resembling any one of an isosceles trapezoid, a square, a rectangular, a semi-circle, a semi-ovoid, or a triangle.

19. The process of claim 13, wherein second substrate is a photoabsorbing substrate.

20. A photovoltaic device, the photovoltaic device produced by a process incorporating the process of claim 13.
